(19) United States
(12) Patent Application Publication
(10) Pub. No.: US 2022/0375721 A1
(43) Pub. Date: Nov. 24, 2022

(54) RADIO FREQUENCY (RF) POWER IMBALANCING IN A MULTI-STATION INTEGRATED CIRCUIT FABRICATION CHAMBER

(71) Applicant: Lam Research Corporation, Fremont, CA (US)

(72) Inventors: Jeremy David Fields, Portland, OR (US); Awnish Gupta, Hillsboro, OR (US); Chun-Hao Chen, Alameda, CA (US); Yaswanth Rangineni, Tigard, OR (US); Frank Loren Pasquale, Tigard, OR (US)

(21) Appl. No.: 17/755,141

(22) PCT Filed: Oct. 23, 2020
(86) PCT No.: PCT/US2020/057020

§ 371 Date: Apr. 21, 2022

Related U.S. Application Data
(60) Provisional application No. 62/925,919, filed on Oct. 25, 2019.

(51) Int. Cl. H01J 37/32; H01L 21/66

(52) U.S. Cl. CPC H01J 37/32183; H01J 37/32091; H01J 37/32899; H01L 22/20; H01J 2237/3327; H01J 2237/3343; H01J 37/3299; H01J 2237/3321

(57) ABSTRACT

Radio frequency power conveyed to individual process stations of a multi-station integrated circuit fabrication chamber may be adjusted so as to bring the rates at which fabrication processes occur, and/or fabrication process results, into alignment with one another. Such adjustment in radio frequency power, which may be accomplished via adjusting one or more reactive elements of a RF distribution network, may give rise to an imbalance in power delivered to each individual process station.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Fabrication of integrated circuit devices may involve the processing of semiconductor wafers in a semiconductor processing chamber. Typical processes may involve deposition, in which a semiconductor material may be deposited, such as in a layer-by-layer fashion, as well as removal (e.g., etching) of material in certain regions of the semiconductor wafer. In commercial scale manufacturing, each wafer contains many copies of a particular semiconductor device being manufactured, and many wafers may be utilized to achieve the required volumes of devices. Accordingly, the commercial viability of a semiconductor processing operation may depend, at least to some extent, upon within-wafer uniformity and upon wafer-to-wafer repeatability of the process conditions. Consequently, efforts are made to ensure that each portion of a given wafer, as well as each wafer processed in a semiconductor processing chamber, undergo the same processing conditions. Variation in the processing conditions can bring about undesirable variations in process conditions and/or process results, which, in turn, may bring about unacceptable variations in an overall fabrication process. Such variations may degrade circuit performance which, in turn, may give rise to unacceptable variations in performance of higher-level systems, for example, that utilize the integrated circuit devices.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Briefly, in certain embodiments, an apparatus to generate RF power may include one or more RF power sources and a RF power distribution network configured to allocate power from the one or more RF power sources to individual input ports of a multi-station integrated circuit fabrication chamber. The RF power distribution network may be additionally configured to apply one or more control parameters to bring about an imbalance in the power from the RF power distribution network to the individual input ports of the multi-station integrated circuit fabrication chamber.

In certain embodiments, the RF power distribution network may include one or more reactive circuit elements. In some embodiments, the apparatus may further include a controller configured to adjust at least one value of the one or more reactive circuit elements responsive to identification of a disparity between a process condition and/or a process result at a first station of the multi-station integrated circuit fabrication chamber and a process condition and/or a process result at a second station of the multi-station integrated circuit fabrication chamber. In certain embodiments, the process may include a deposition process, such as atomic layer deposition, plasma-enhanced chemical vapor deposition, or may include an etching process. In some embodiments, the one or more reactive circuit elements of the apparatus may include at least one capacitor or at least one inductor. In addition, the one or more control parameters may include modification of a value of the at least one capacitor to between about 10% and about 90% of a maximum value of capacitance.

In an embodiment, a multi-station integrated circuit fabrication chamber may include one or more output ports, in which each output port is configured to receive a signal from one or more RF power sources. The multi-station integrated circuit fabrication chamber may further include a RF power distribution network, coupled to a corresponding one of the one or more input ports, in which the RF power distribution network includes one or more reactive circuit elements. The fabrication chamber may further include a controller coupled to the RF power distribution network and configured to modify a value of the one or more reactive circuit elements to give rise to an imbalance in RF power coupled from the one or more RF power sources to the multi-station integrated circuit fabrication chamber.

In some embodiments, the multi-station integrated circuit fabrication chamber includes four process stations. In some embodiments, the multi-station integrated circuit fabrication chamber includes two process stations. In some embodiments, the multi-station integrated circuit fabrication chamber includes 8 process stations. In some embodiments, the multi-station integrated circuit fabrication chamber includes 16 process stations.

In certain embodiments, the one or more reactive circuit elements may include one or more capacitors. In certain embodiments a controller may be configured to modify a value of capacitance of the one or more capacitors from between about 10% of a maximum value to about 90% of the maximum value. In certain embodiments, a controller of the fabrication chamber may be configured to modify the value of the reactive circuit element responsive to identifying a difference between a process condition and/or a process result at a first station of the multi-station integrated circuit fabrication chamber and a process condition and/or a process result at a second station of the multi-station integrated circuit fabrication chamber. In some embodiments, the process may include a deposition process. In some embodiments, the process may include an etching process.

In certain embodiments, a control module may include a hardware processor coupled to a memory and a communications port, the communications port may be configured to receive an indication that a process condition and/or a process result at a first station of a multi-station integrated circuit fabrication chamber is different than a process condition and/or a process result at a second station of a multi-station integrated circuit fabrication chamber. The communications port may be configured to additionally transmit one or more instructions to a RF power distribution network to bring about an imbalance in RF power coupled to the first station of the multi-station integrated circuit fabrication chamber with respect to the RF power coupled to the second station of the multi-station integrated circuit fabrication chamber.

In certain embodiments, the one or more instructions operate to modify a value of one or more reactive elements of the RF power distribution network. In certain embodiments, the one or more reactive elements includes at least one capacitor and the one or more instructions operates to modify the value of the at least one capacitor to between about 10% and about 90% of a maximum value.

In certain embodiments, a method for controlling a fabrication process may include identifying that a process condition and/or a process result at a first station of a multi-station integrated circuit fabrication chamber is different than a process condition and/or a process result at a second station of the multi-station integrated circuit fabrication chamber. The method may further include imbalancing RF power coupled to the first station of the multi-station integrated circuit fabrication chamber with respect to the RF power coupled to the second station of the multi-station integrated circuit fabrication chamber.

In some embodiments, imbalancing may include modifying a value of a reactive circuit element of a RF power distribution network coupled to an input port of the multi-station integrated circuit fabrication chamber. In some embodiments, modifying the value of the reactive circuit element may include adjusting the capacitance of the reactive circuit element from a nominal value of about 50% of a maximum value of capacitance to a value of between about 10% and about 90% of the maximum value of capacitance. In some embodiments, imbalancing may include generating at least about a 1% difference between RF power coupled to the first station of the multi-station integrated circuit fabrication chamber with respect to the second station of the multi-station integrated circuit fabrication chamber. In some embodiments, the process may include a deposition process. In some embodiments, the process may include an etching process.

### BRIEF DESCRIPTION OF THE DRAWINGS

FIG. 1 shows a substrate processing apparatus for depositing a film on or over a semiconductor substrate utilizing any number of processes, according to embodiment.

FIG. 2 depicts a schematic view of an embodiment of a multi-station processing tool, according to an embodiment.

FIG. 3 depicts a schematic view of an embodiment of a multi-station processing tool wherein an imbalance may be introduced into one or more stations, according to an embodiment.

FIG. 4 is a flowchart for a method of imbalancing RF power to one or more stations of a multi-station integrated circuit fabrication chamber, according to an embodiment.

FIG. 5 is a graph showing the mean thickness of a material deposited under a RF power balanced condition and under a RF power imbalanced condition, according to an embodiment.

FIG. 6 is a graph showing etch rate of a semiconductor material under a RF power balanced condition and under a RF power imbalanced condition, according to an embodiment.

FIG. 7 is a graph showing leakage current of a film deposited on a wafer at a process station under conditions of relatively high and relatively low RF power conditions, according to an embodiment.

### DETAILED DESCRIPTION

In particular embodiments, RF power imbalancing may be utilized in conjunction with a variety of equipment involved in the fabrication of integrated circuits, such as equipment related to plasma-based or plasma-assisted integrated circuit fabrication. Such equipment may involve multi-station fabrication chambers, such as those in which multiple integrated circuit wafers simultaneously undergo fabrication processes. In certain embodiments, plasma-based and/or plasma-assisted fabrication processes involving multi-station fabrication chambers may benefit from a capability to bring about a station-to-station imbalance in a power level of a RF signal coupled to one or more individual stations. Such coupling of disparate signal amplitudes among individual stations of a multi-station integrated circuit fabrication chamber may operate to increase uniformity in fabrication processes, such as plasma-based film deposition and plasma-based material etching. Consequently, processes to form integrated circuits by way of multi-station fabrication chambers may be performed with greater accuracy which, in turn, may result in lower defect ratios and/or higher yields of devices formed utilizing the fabrication chamber.

In certain embodiments, creation of an imbalance in RF power coupled to individual stations of a multi-station integrated circuit fabrication chamber may at least partially compensate for station-to-station nonuniformities, which may affect conditions and/or results of processes occurring within the fabrication chamber. Such process conditions and/or process results may involve film deposition rates, etch rates, film electrical quality (e.g., leakage current) or other parameters. Nonuniformities that may bring about differences in process conditions and/or process results may include station-to-station variations in precursor gas concentrations utilized, for example, in atomic layer deposition (ALD) processes, variations in precursor gas temperatures, station-specific geometrical variations, station-to-station variations in RF coupling structures, and so forth. In particular embodiments, film deposition and/or material etch rates occurring at a first station, for example, may be increased while deposition/etch rates occurring at a second station, for example, may be decreased. Accordingly, film deposition and/or material etching may be performed with increased consistency and regularity.

Although embodiments of claimed subject matter are not bound to any particular theory, it is contemplated that station-to-station variations may give rise to differing values of a complex impedance presented by a process station. Thus, for example, despite attempts to construct and operate process stations of a multi-station fabrication chamber in a manner that presents identical impedances to RF power sources, variations among process stations may give rise to variations in a load presented to a RF source. Accordingly, as a load presented by a process station diverges from a nominal complex impedance value, power may be reflected from the process station and in the direction back towards the generator. Thus, as a consequence of such occasional variations in a load presented by a process chamber, actual power delivered to any particular process station during wafer fabrication may vary significantly.

Particular embodiments may represent improvements over other approaches of coupling RF power to process stations of a multi-station integrated circuit fabrication chamber. For example, in some instances, balanced or uniform coupling of RF power to process stations, in which RF power may be divided evenly among process stations, may nonetheless give rise to significant variances in process conditions and/or process results, such as semiconductor film deposition/etch rates. In particular instances, despite balancing of RF power coupled to individual process stations of a multi-station integrated circuit fabrication chamber, material etch rates may vary by, for example, from about 12% to about 20%, or more. In other instances, balancing of RF power to individual process stations of a multi-station integrated circuit fabrication chamber may result in film deposition rates that may vary by about 5% to about 10%, or more. In still other instances, use of balanced RF power may bring about film deposition rates that are relatively consistent or matched with one another (at least to within customer specifications) while etch rates may be relatively inconsistent or unmatched with one another. In these instances, it may be possible to adjust RF power to give rise to a balanced etch rate and utilize one or more other techniques to match total film thickness.

As discussed herein, imbalancing of RF power coupled to individual process stations of a multi-station integrated circuit fabrication chamber may be accomplished without affecting the output power from a RF generator. For example, in particular embodiments, a RF generator may be configured to provide a substantially constant output power, such as an output power of between about 1.5 kW and about 2 kW. Control over RF power coupled to an individual process station of a multi-station fabrication chamber may be controlled or modulated by way of adjusting one or more reactive elements of a RF power distribution network coupled or linked to a particular process station. Thus, via an adjustment to a reactive element of a RF power distribution network, which may include performing an adjustment to a variable capacitor and/or a variable inductor of a RF power distribution network, a predetermined amount of power delivered to a process station may be increased or decreased. Such increasing or decreasing of power delivered to one or more process stations may permit adjustment of a rate at which a process occurs at the one or more process stations. Such adjustment may bring about harmonization of a fabrication processes and/or results with respect to one or more other process stations of a multi-station integrated circuit fabrication chamber. In this context, a reactive circuit element refers to any lumped or distributed element of an electrical circuit that operates to modify a phase relationship between a voltage and current of an electrical signal. Thus, for example, reactive circuit elements may include inductors, capacitors, or any other device that operates to modify the phase relationship between a current and voltage signal.

Certain embodiments and implementations may be utilized with a number of wafer fabrication processes, such as various plasma-enhanced atomic layer deposition (ALD) processes (e.g., ALD1, ALD2), various plasma-enhanced chemical vapor deposition (e.g., PECVD1, PECVD2, PECVD3) processes, or may be utilized on-the-fly during single deposition processes. In certain embodiments, a RF power generator having multiple output ports may be utilized at any signal frequency, such as at frequencies between about 300 kHz and about 60 MHz, which may include frequencies of about 400 kHz, about 1 MHz, about 2 MHz, 13.56 MHz, 13.83 MHz, and 27.12 MHz However, in other embodiments, RF power generators having multiple output ports may operate at any signal frequency, which may include relatively low frequencies, such as between about 50 kHz and about 300 kHz, as well as higher signal frequencies, such as frequencies between about 60 MHz and about 100 MHz, virtually without limitation.

It should be noted that although particular embodiments described herein may show and/or describe RF power generators having a single output port in which output power may be divided among four process stations of a four-station integrated circuit fabrication chamber, claimed subject matter is intended to embrace multi-station integrated circuit fabrication chambers having any number of process stations. Thus, in some embodiments, an output port of a RF power generator may be assigned to a process station of a multi-station fabrication chamber having, for example, two process stations or three process stations. In other embodiments an output port of a RF power generator may be assigned to process stations of a multi-station integrated circuit fabrication chamber having a larger number of process stations, such as five process stations, six process stations, seven process stations, eight process stations, or any other number of process stations, virtually without limitation.

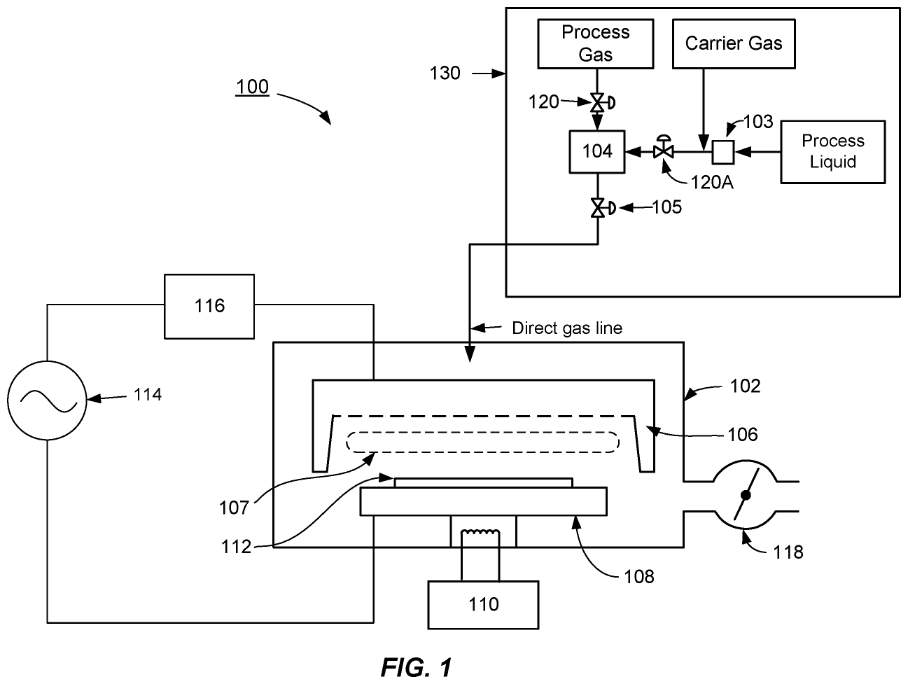

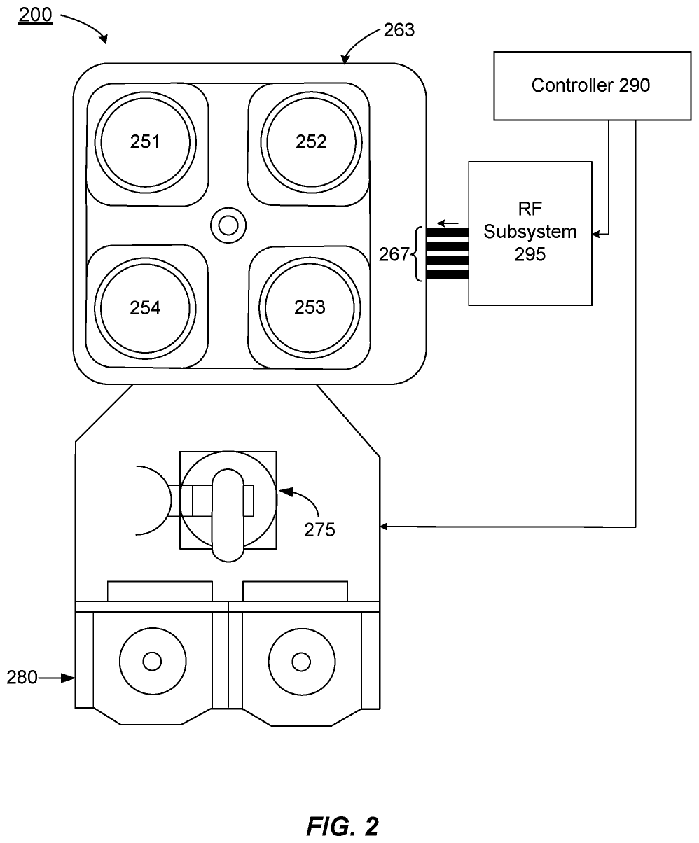

Manufacture of semiconductor devices typically involves depositing one or more thin films on or over a planar or non-planar substrate in an integrated fabrication process. In some aspects of an integrated process, it may be useful to deposit thin films that conform to unique substrate topography. One type of reaction that is useful in some cases involves chemical vapor deposition (CVD). In typical CVD processes, gas phase reactants introduced into stations of a reaction chamber simultaneously undergo a gas-phase reaction. The products of the gas-phase reaction deposit on the surface of the substrate. A reaction of this type may be driven, enhanced, or assisted by presence of a plasma, in which case the process may be referred to as a plasma-enhanced chemical vapor deposition (PECVD) reaction. As used herein, the term CVD is intended to include PECVD unless otherwise indicated. CVD processes have certain disadvantages that render them less appropriate in some contexts. For instance, mass transport limitations of CVD gas phase reactions may bring about deposition effects that exhibit thicker deposition at top surfaces (e.g., top surfaces of gate stacks) and thinner deposition at recessed surfaces (e.g., bottom corners of gate stacks). Further, in response to some semiconductor die having regions of differing device density, mass transport effects across the substrate surface may result in within-die and within-wafer thickness variations. Thus, during subsequent etching processes, thickness variations can result in over-etching of some regions and under-etching of other regions, which can degrade device performance and die yield. Another difficulty related to CVD processes is that such processes are often unable to deposit conformal films in high aspect ratio features. This issue can be increasingly problematic as device dimensions continue to shrink. These and other drawbacks of particular aspects of wafer fabrication processes are discussed in relation to FIGS. 1 and 2.

In another example, some deposition processes involve multiple film deposition cycles, each producing a discrete film thickness. For example, in atomic layer deposition (ALD), thickness of a deposited layer may be limited by an amount of one or more film precursor reactants which may adsorb onto a substrate surface, so as to form an adsorption-limited layer, prior to the film-forming chemical reaction itself. Thus, a feature of ALD involves the formation of thin layers of film (such as layers having a width of a single atom or molecule) are used in a repeating and sequential matter. As device and feature sizes continue to be reduced in scale, and as three-dimensional devices and structures become more prevalent in integrated circuit (IC) design, the capability of depositing thin conformal films (e.g., films of material having a uniform thickness relative to the shape of the underlying structure) continues to gain in importance. Thus, in view of ALD being a film-forming technique in which each deposition cycle operates to deposit a single atomic or molecular layer of material. ALD may be well-suited to the deposition of conformal films. Typical device fabrication processes involving ALD may include multiple ALD cycles, which may number into the hundreds or thousands, may then be utilized to form films of virtually any desired thickness. Further, in view of each layer being thin and conformal, a film that results from such a process may conform to a shape of any underlying device structure. In certain embodiments, an ALD cycle may include the following steps:

Exposure of the substrate surface to a first precursor.

Purge of the reaction chamber in which the substrate is located.

Activation of a reaction of the substrate surface, typically with a plasma and/or a second precursor.

Purge of the reaction chamber in which the substrate is located.

The duration of each ALD cycle may typically be less than about 25 seconds or less than about 10 seconds or less than about 5 seconds. The plasma exposure step (or steps) of the ALD cycle may be of a short duration, such as a duration of about 1 second or less. In some instances, an entire ALD cycle may consume less than 1 second.

Turning now to the figures, FIG. 1 shows a substrate processing apparatus 100 for depositing films on semiconductor substrates utilizing any number of processes, according to various embodiments. Processing apparatus 100 of FIG. 1 utilizes single process station 102 of a process chamber with a single substrate holder, such as pedestal 108, in an interior volume, which may be maintained under vacuum responsive to operation of vacuum pump 118. Showerhead 106 and gas delivery system 130, which may be fluidically coupled to the process chamber, may permit the delivery of film precursors, for example, as well as carrier and/or purge and/or process gases, precursor gases, secondary reactants, and so forth. Equipment utilized in the generation of plasma within the process chamber is also shown in FIG. 1. The apparatus schematically illustrated in FIG. 1 may be adapted for performing, in particular, PECVD.

In FIG. 1, gas delivery system 130 includes a mixing vessel 104, which may operate to blend and/or condition precursor and/or process gases for delivery to showerhead 106. One or more mixing vessel inlet valves 120 may control introduction of precursor and/or gases to mixing vessel 104. Particular reactants may be stored in liquid form prior to vaporization and subsequent delivery to process station 102 of a process chamber. The embodiment of FIG. 1 includes a vaporization point 103 for vaporizing liquid reactant to be supplied to mixing vessel 104. In some implementations, vaporization point 103 may comprise a heated liquid injection module. In some other implementations, vaporization point 103 may comprise a heated vaporizer. In yet other implementations, vaporization point 103 may be eliminated from the process station. In some implementations, a liquid flow controller (LFC) located upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which is controlled by one or more valves upstream from the showerhead (e.g., valves 120, 120A, 105). In the embodiment depicted in FIG. 1, substrate 112 is depicted as located under showerhead 106, and is shown resting on a pedestal 108. Showerhead 106 may comprise any suitable shape, and may include any suitable number and arrangement of ports for distributing process gases to substrate 112. In some embodiments with two or more stations, gas delivery system 130 includes valves and/or other flow control structures upstream of showerhead 106, which can independently control the flow of process gases and/or reactants to each station so as to permit gas flow cut that to one station while prohibiting gas flow to a second station. Furthermore, gas delivery system 130 may be configured to independently control process gases and/or reactants delivered to each station in a multi-station integrated circuit fabrication apparatus such that the gas composition provided to different stations is different; e.g., the partial pressure of a gas component may vary between stations at the same time.

In FIG. 1, volume 107 is depicted as being located beneath showerhead 106. In some implementations, pedestal 108 may be raised or lowered so as to expose substrate 112 to volume 107 and/or to vary the size of volume 107. Optionally, pedestal 108 may be lowered and/or raised during portions of the deposition process to modulate process pressure, reactant concentration, etc., within volume 107. Showerhead 106 and pedestal 108 are depicted as being electrically coupled to radio frequency power supply 114 and matching network 116 for coupling power to a plasma generator. Thus, showerhead 106 may function as an electrode for coupling radio frequency power into process station 102. In some implementations, the plasma energy is controlled (e.g., via a system controller having appropriate machine-readable instructions and/or control logic) by controlling one or more of a process station pressure, a gas concentration, a RF power generator, and so forth. For example, radio frequency power supply 114 and matching network 116 may be operated at any suitable RF power level, which may operate to form plasma having a desired composition of radical species. Likewise, RF power supply 114 may provide RF power of any suitable frequency, or group of frequencies, and power level.

In some implementations, the plasma ignition and maintenance conditions are controlled with appropriate hardware and/or appropriate machine-readable instructions in a system controller which may provide control instructions via a sequence of input/output control (IOC) instructions. In one example, the instructions for bringing about ignition or maintaining a plasma are provided in the form of a plasma activation recipe of a process recipe. In some cases, process recipes may be sequentially arranged, so that at least some instructions for the process can be executed concurrently. In some implementations, instructions for setting one or more plasma parameters may be included in a recipe preceding a plasma ignition process. For example, a first recipe may include instructions for setting a flow rate of an inert (e.g., helium) and/or a reactant gas, instructions for setting a plasma generator to a power set point and time delay instructions for the first recipe. A second, subsequent recipe may include instructions for enabling the plasma generator and time delay instructions for the second recipe. A third recipe may include instructions for disabling the plasma generator and time delay instructions for the third recipe. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example.

For simplicity, processing apparatus 100 is depicted in FIG. 1 as a standalone station (102) of a process chamber for maintaining a low-pressure environment. However, it may be appreciated that a plurality of process stations may be included in a multi-station processing tool environment, such as shown in FIG. 2, which depicts a schematic view of an embodiment of a multi-station processing tool. Processing apparatus 200 employs an integrated circuit fabrication chamber 263 that includes multiple fabrication process stations, each of which may be used to perform processing operations on a substrate held in a wafer holder, such as pedestal 108 of FIG. 1, at a particular process station. In the embodiment of FIG. 2, the integrated circuit fabrication chamber 263 is shown having four process stations 251, 252, 253, and 254. Other similar multi-station processing apparatuses may have more or fewer process stations depending on the implementation and, for example, a desired level of parallel wafer processing, size/space constraints, cost constraints, etc. Also shown in FIG. 2 is substrate handler robot 275, which may operate under the control of system controller 290, configured to move substrates from a wafer cassette (not shown in FIG. 2) from loading port 280 and into integrated circuit fabrication chamber 263, and onto one of process stations 251, 252, 253, and 254.

FIG. 2 also depicts an embodiment of a system controller 290 employed to control process conditions and hardware states of processing apparatus 200. System controller 290 may include one or more memory devices, one or more mass storage devices, and one or more processors. The one or more processors may include a central processing unit, analog and/or digital input/output connections, stepper motor controller boards, etc. In some embodiments, system controller 290 controls all of the activities of processing tool 200. System controller 290 executes system control software stored in a mass storage device, which may be loaded into a memory device, and executed on a hardware processor of the system controller. Software to be executed by a processor of system controller 290 may include instructions for controlling the timing, mixture of gases, fabrication chamber and/or station pressure, fabrication chamber and/or station temperature, wafer temperature, substrate pedestal, chuck and/or susceptor position, number of cycles performed on one or more substrates, and other parameters of a particular process performed by processing tool 200. These programed processes may include various types of processes including, but not limited to, processes related to determining an amount of accumulation on a surface of the chamber interior, processes related to deposition of film on substrates including numbers of cycles, and processes related to cleaning the chamber. System control software, which may be executed by one or more processors of system controller 290, may be configured in any suitable way. For example, various process tool component subroutines or control objects may be written to control operation of the process tool components necessary to carry out various tool processes.

In some embodiments, software for execution by way of a processor of system controller 290 may include input/output control (IOC) sequencing instructions for controlling the various parameters described above. For example, each phase of deposition and deposition cycling of a substrate may include one or more instructions for execution by system controller 290. The instructions for setting process conditions for an ALD/CFD deposition process phase may be included in a corresponding ALD/CFD deposition recipe phase. In some embodiments, the recipe phases may be sequentially arranged, so that all instructions for a process phase are executed concurrently with that process phase.

Other computer software and/or programs stored on a mass storage device of system controller 290 and/or a memory device accessible to system controller 290 may be employed in some embodiments. Examples of programs or sections of programs for this purpose include a substrate positioning program, a process gas control program, a pressure control program, a heater control program, and a plasma control program. A substrate positioning program may include program code for process tool components that are used to load the substrate onto pedestal 108 (of FIG. 2) and to control the spacing between the substrate and other parts of processing apparatus 200. A positioning program may include instructions for appropriately moving substrates in and out of the reaction chamber as necessary to deposit films on substrates and clean the chamber.

A process gas control program may include code for controlling gas composition and flow rates and optionally for flowing gas into one or more process stations prior to deposition in order to stabilize the pressure in the process station. In some embodiments, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing number of cycles on one or more substrates during the processing of the batch.

A heater control program may include code for controlling the current to heating unit 110 (of FIG. 1) that is used to heat the substrate. Alternatively, the heater control program may control delivery of a heat transfer gas (such as helium) to the substrate.

In some embodiments, there may be a user interface associated with system controller 290. The user interface may include a display screen, graphical software displays of the apparatus and/or process conditions, and user input devices such as pointing devices, keyboards, touch screens, microphones, etc.

In some embodiments, parameters adjusted by system controller 290 may relate to process conditions. Non-limiting examples include process gas composition and flow rates, temperature, pressure, plasma conditions, etc. These parameters may be provided to the user in the form of a recipe, which may be entered utilizing the user interface. The recipe for an entire batch of substrates may include compensated cycle counts for one or more substrates within the batch in order to account for thickness trending over the course of processing the batch.

Signals for monitoring the process may be provided by analog and/or digital input connections of system controller 290 from various process tool sensors. The signals for controlling the process may be output by way of the analog and/or digital output connections of processing tool 200. Non-limiting examples of process tool sensors that may be monitored include mass flow controllers, pressure sensors (such as manometers), thermocouples, etc. Sensors may also be included and used to monitor and determine the accumulation on one or more surfaces of the interior of the chamber and/or the thickness of a material layer on a substrate in the chamber. Appropriately programmed feedback and control algorithms may be used with data from these sensors to maintain process conditions.

System controller 290 may provide program instructions for implementing the above-described deposition processes. The program instructions may control a variety of process parameters, such as DC power level, pressure, temperature, number of cycles for a substrate, amount of accumulation on at least one surface of the chamber interior, etc. The instructions may control the parameters to operate in-situ deposition of film stacks according to various embodiments described herein.

For example, the system controller may include control logic for performing the techniques described herein, such as determining an amount of accumulated deposition material currently on at least an interior region of the deposition chamber interior, applying the determine the amount of deposited material, or a parameter derived therefrom, to a relationship between (i) a number of ALD cycles required to achieve a target deposition thickness, and (ii) a variable representing an amount of accumulated deposition material, in order to obtain a compensated number of ALD cycles for producing the target deposition thickness given the amount of accumulated deposition material currently on the interior region of the deposition chamber interior, and performing the compensated number of ALD cycles on one or more substrates in the batch of substrates. The system may also include control logic for determining that the accumulation in the chamber has reached an accumulation limit and stopping the processing of the batch of substrates in response to that determination, and for causing a cleaning of the chamber interior.

In addition to the above-identified functions and/or operations performed by system controller 290 of FIG. 2, the controller may additionally control and/or manage the operations of RF subsystem 295, which may generate and convey RF power to integrated circuit fabrication chamber 263 via radio frequency input ports 267. As described further herein, such operations may relate to, for example, determining upper and lower thresholds for RF power to be delivered to integrated circuit fabrication chamber 263, determining actual (such as real-time) levels of RF power delivered to integrated circuit fabrication chamber 263, RF power activation/deactivation times, RF power on/off duration, operating frequency, and so forth.

In particular embodiments, integrated circuit fabrication chamber 263 may comprise input ports in addition to input ports 267 (additional input ports not shown in FIG. 2). Accordingly, integrated circuit fabrication chamber 263 may utilize 8 RF input ports. In particular embodiments, process stations 251-254 of integrated circuit fabrication chamber 165 may each utilize first and second input ports in which a first input port may convey a signal having a first frequency and in which a second input port may convey a signal having a second frequency. Use of dual frequencies may bring about enhanced plasma characteristics, which may give rise to deposition rates within particular limits and/or more easily controlled deposition rates. Dual frequencies may bring about other desirable consequences, and claimed subject matter is not limited in this respect. In certain embodiments, frequencies of between about 300 kHz and about 65 MHz may be utilized. In some implementations, signal frequencies of about 2 MHz or less may be referred to as low frequency (LF) while frequencies greater than about 2 MHz may be referred to as high frequency (HF).

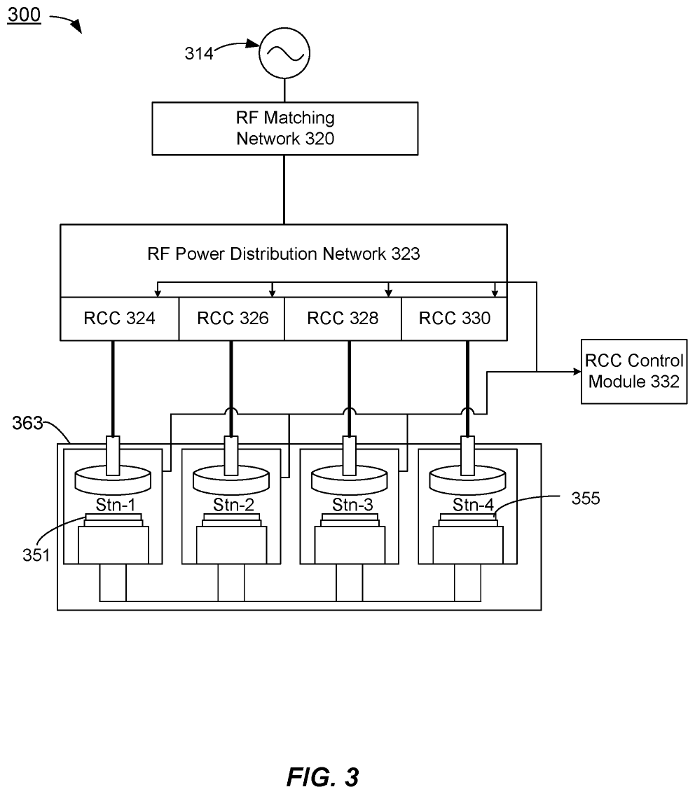

FIG. 3 depicts a schematic view of an embodiment of a multi-station fabrication chamber wherein an imbalance may be introduced into one or more stations, according to an embodiment 300. In this context, an imbalance may comprise a deviation from a condition in which substantially equal power is coupled to an input port of a process station of a multi-station fabrication chamber to a condition in which an unequal amount of power is coupled to the input port of the process station. In particular embodiments, a balanced condition refers to a condition in which there is less than about a 1% deviation in RF power coupled to each process station. Accordingly, in such embodiments, an imbalanced condition refers to a condition in which there is greater than about a 1% deviation in RF power coupled to each process station. In certain embodiments, a balanced condition refers to a condition in which there is less than about a 2% deviation in RF power coupled to each process station. Accordingly, in such embodiments, an imbalanced condition refers to a condition in which there is greater than about a 2% deviation in RF power coupled to each process station. In other embodiments, a balanced condition refers to a condition in which there is less than about a 2.5% deviation in RF power coupled to each process station. Accordingly, in such embodiments, an imbalanced condition refers to a condition in which there is greater than about a 2.5% deviation in RF power coupled to each process station. In other embodiments, a balanced condition refers to a condition in which there is less than about a 5% deviation in RF power coupled to each process station. Accordingly, in such embodiments, an imbalanced condition refers to a condition in which there is greater than about a 5% deviation in RF power coupled to each process station.

As described in reference to FIG. 3, RF power generator 314 may include a single output signal path so as to couple a relatively high-power output signal to RF matching network 320. In the embodiment of FIG. 3, RF matching network 320 operates to provide an input impedance that matches an output impedance of RF power generator 314. Thus, in certain embodiments in which RF power generator 314 provides an output impedance of about 50 ohms, RF matching network 320 may provide a matching (50 ohm) input impedance. RF power generator 314 may generate a signal having an amplitude of 1.5 kW; however, claimed subject matter is intended to embrace RF power generators having a wide variety of output power levels, such as output levels less than 1.5 kW (e.g., 750 W, 1 kW, 1.25 kW, etc. In other embodiments, RF power generator 314 may generate a signal having an amplitude greater than 1.5 kW, such as power outputs of 1.75 kW, 2 kW, 2.5 kW, and so forth, virtually without limitation.

In the embodiment of FIG. 3, RF power distribution network 323 is configured to allocate RF power among process stations of a multi-station integrated circuit fabrication chamber. In particular embodiments, RF power distribution network 323 receives a relatively high-power input signal from RF matching network 320 for distribution among four process stations, depicted as Stn-1, Stn-2, Stn-3, and Stn-4, which represent process stations of multi-station integrated circuit fabrication chamber 363. In embodiments other than that of FIG. 3, a RF distribution module may allocate power among any number of process stations, such as fewer than 4 process stations (e.g., 2 process stations or 3 process stations) or greater than 4 process stations (e.g., 5 process stations, 6 process stations, 8 process stations, 16 process stations, and so forth) and claimed subject matter is not limited in this respect.

In the embodiment of FIG. 3, RF power distribution network 323 includes recipe-controlled capacitance (RCC) modules 324, 326, 328, and 330. RCC modules include at least one tunable capacitive element, which, in response to receipt of one or more control parameters from RCC control module 332, may operate to add or subtract a capacitive reactance to one or more output signals from RF power distribution network 323. Thus, RCC modules 324, 326, 328, and 330 may operate as a RF power distribution network that operates to bring about a precise match between the impedance of an output port of RF power distribution network 323 and the impedance of an input port of a corresponding process station (e.g., Stn-1. Stn-2, Stn-3, and Stn-4) by way of adjusting a capacitive reactance of an individual RCC module. Additionally, RCC modules 324-330 may bring about an intentional mismatch between the input port of a corresponding process station, so as to give rise to an imbalance, in which a fraction of the RF power conveyed to a process station may be reflected toward the output port of RF power generator 314.

Accordingly, at least during certain initial or baseline operations of process stations Stn-1-Stn-4, RCC control module 332 may direct RF power distribution network 323 to set capacitive reactances introduced by RCC modules 324-330 to a baseline or nominal value, such as a midpoint within a tunable range. In particular embodiments, a midpoint within a tunable range of capacitance may correspond to a value of about 50% of a maximum attainable value by each of RCC modules 324-330. In such instances, RCC modules 324-330 may cooperate with RF power distribution network 323 to provide substantially equal power to each process station of multi-station integrated circuit fabrication chamber 363. In one particular example among many possible examples, RF power provided to individual stations of multi-station fabrication chamber may equal about 450 W.

However, as fabrication processes occur within each process station of multi-station integrated circuit fabrication chamber 363, variations in conditions may bring about undesirable variations in process results. Such variations may include nonuniformities in film deposition rates occurring during an ALD process, for example, material etch rates occurring during wet or dry etching operations, or other fabrication processes. In addition, nonuniformities in fabrication processes may bring about undesirable variances in electrical properties, such as film resistivity and film dielectric constant. Further, nonuniformnities in fabrication processes may give rise to undesirable physical properties, such as film density, in which use of lower RF power levels may result in less compacted films that etch more rapidly than more compacted films produced utilizing higher RF power levels. As mentioned previously herein, variations in processing conditions may be brought about by disparities in precursor gas concentrations utilized in ALD processes, variations in precursor gas temperatures, station-specific geometrical variations, station-to-station variations in RF coupling structures, and so forth. Thus, for example, during ALD operations, thickness of an integrated circuit film, such as a film being formed on wafer 351 within process station Stn-1, may comprise a greater thickness than a film being formed on wafer 355 at Stn-4. In particular embodiments, such variations in film thickness may degrade circuit performance which, in turn, may give rise to unacceptable variations in performance of higher-level systems, for example, that utilize the integrated circuit devices undergoing fabrication at Stn-1-Stn-4 of the multi-station integrated circuit fabrication chamber 363.

Responsive to detection of differences in film formation rates, for example, occurring within process stations Stn-1-Stn-4 of multi-station integrated circuit fabrication chamber 363, RCC control module 332 may direct one or more of RCC modules 324-330 to vary a capacitance introduced by a reactive circuit element within the one or more of RCC modules 324-330. In particular embodiments, such control over the value of a reactive circuit element of an RCC module may be brought about by control of a stepper motor within an RCC module, which may operate to slide or insert one or more plates between stationary capacitor plates. Accordingly, in one example, responsive to RCC control module 332 detecting that a film deposition rate occurring within Stn-1 is decreased relative to film formation rates occurring in other stations of multi-station integrated circuit fabrication chamber 363, RCC control module 332 may direct RCC module 324 to reduce capacitive reactance. In particular embodiments, such reduction of capacitive reactance may operate to increase relative power conveyed to Stn-1. Thus, over time, a film deposition rate occurring at Stn-1 may increase so as to be brought into parity with film deposition rates occurring at other process stations.

In the context of the example of FIG. 3, RCC modules 324, 326, 328, and 330 have been described as comprising circuit elements that provide capacitive reactance. In particular embodiments, circuit elements that provide variable, tunable capacitance may possess certain implementation advantages over circuit elements that provide variable, tunable inductance. However, in certain embodiments reactive circuit elements that provide variable, tunable inductance may be advantageous, and claimed subject matter is intended to embrace RCC modules employing either capacitive or inductive circuit elements.

It should be noted that although RF power generator 314 of FIG. 3 has been described as comprising a single RF power generator, in particular embodiments, RF power generator 314 may comprise an aggregate of more than one RF power generator. In some instances, use of two or more RF power generators may provide some level of redundancy in the event that a RF power generator experiences a failure resulting in suspension of RF power generation. Use of two or more RF generators may provide additional benefits, and claimed subject matter is not limited in this respect. In particular embodiments in which RF power generator 314 comprises an aggregate of two or more individual RF power generators, RF power distribution network 323 may operate to combine RF power from the two or more individual RF power generators in addition to distributing RF power to input ports of a multi-station integrated circuit fabrication chamber.

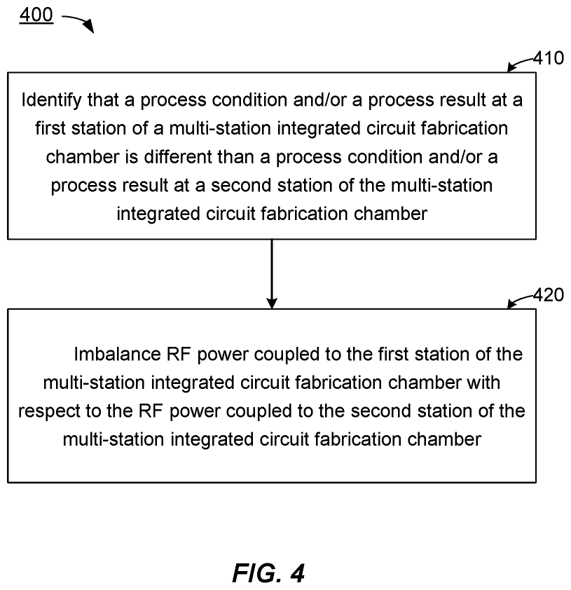

FIG. 4 is a flowchart for a method 400 of imbalancing RF power to one or more stations of a multi-station integrated circuit fabrication chamber, according to an embodiment. Embodiments of claimed subject matter may include actions in addition to those described in method 400, fewer actions than those described in method 400, or actions performed in an order different than described in method 400. Additionally, the apparatus of FIG. 3 may be suitable for performing the method of FIG. 4, although claimed subject matter is intended to embrace performing method of FIG. 4 utilizing alternative systems and/or apparatuses. The method of FIG. 4 may begin at 410, which may comprise identifying that a process condition and/or a process result at a first station of a multi-station integrated circuit fabrication chamber is different than a process condition and/or a process result at a second station of the multi-station integrated circuit fabrication chamber. Such processes may include film deposition processes, such as ALD. PECVD, for example. Processes may also include wet or dry etching processes.

The method may continue at 420, which may include imbalancing RF power coupled to the first station of the multi-station integrated circuit fabrication chamber with respect to the RF power coupled to the second station of the multi-station integrated circuit fabrication chamber. Such imbalancing may comprise modifying a value of one or more reactive elements of a RF power distribution network at an input to the multi-station integrated circuit fabrication chamber. In particular embodiments, such modifying of the value of the reactive circuit elements may comprise adjusting the capacitance from a nominal value of about 50% of a maximum value of capacitance to a value of between about 10% and about 90% of the maximum value.

In particular embodiments, identifying station-to-station nonuniformity in a process condition and/or process result, such as described in reference to 410, may be utilized as an input signal to a feedback loop. Identification of a nonuniformity may, without user input (e.g., automatically), bring about an imbalance in RF power delivered to the individual process stations at which the nonuniformity occurs. Input signals to such a feedback loop may utilize various techniques to measure a non-uniformity among process stations, and such techniques may be employed within a chamber during processing. Techniques employed within a chamber during a fabrication process may include, for example, measurement of precursor or reagent gas concentration, gas temperature etc. Techniques utilized outside of a reaction chamber, which may be employed after completion of wafer processing, may include measurement of the weight of a wafer, wafer topological feature measurements (e.g., critical dimension, etch profile, deposit conformation, deposition film thickness, and so forth), physical and/or chemical properties of a processed wafer, etch rate, etch depth, and electrical and/or optical properties of the wafer (e.g., sheet resistance, breakdown voltage, dielectric constant, refractive index, reflectance spectrum, etc.). These measurements, and potentially others, may be made with an integrated tool such as an integrated metrology module that may be served by infrastructure (e.g., robots) that attend to the process chambers. The measurements may also be made by a non-integrated metrology tool.

Differences in measured properties of a wafer may be provided as input parameters to a model or other process logic that processes the input parameters and returns output parameters that specify the precise manner of adjustment in, for example, amplitude, frequency content, etc., of RF power to be coupled to individual stations of a multi-chamber integrated circuit fabrication chamber. Such modifications in characteristics of RF power coupled to the chamber may bring about a reduction in station-to-station non-uniformity. Adjustments may be made iteratively, such as over multiple cycles of processing multiple wafers. Updated determinations in station-to-station nonuniformity levels may be provided to the model or to other process logic, which may be utilized to further update or modify station-to-station RF power levels based on the model output. In some instances, a model may incorporate a relationship between a processed wafer parameter value (e.g., thickness or breakdown voltage) and a corresponding RF power level. In certain embodiments, a model may incorporate one or more sensitivity relationships between a level of nonuniformity between stations and a corresponding corrective RF imbalance between the same stations.

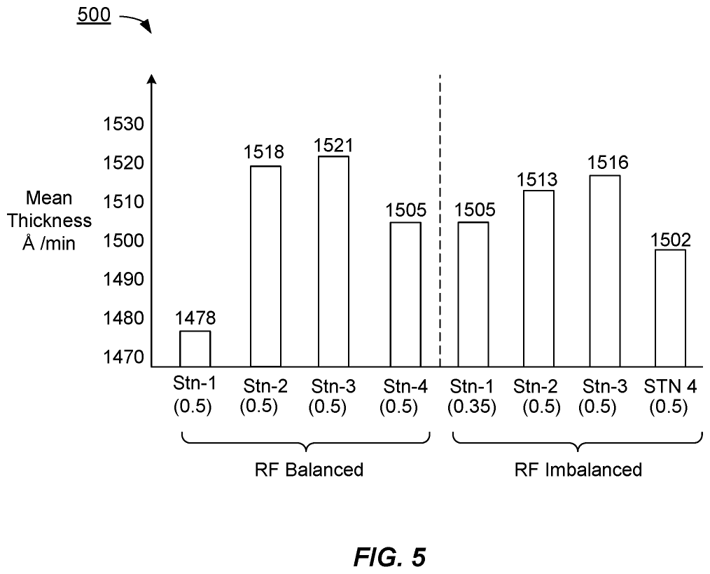

FIG. 5 is a graph showing the mean thickness of a material deposited under a RF power balanced condition and under a RF power imbalanced condition, according to an embodiment 500. The apparatus of FIG. 3 may be suitable performing the deposition process resulting in the graph of FIG. 5, although deposition processes may be brought about utilizing other arrangements of equipment, and claimed subject matter is not limited in this respect. The vertical axis of the graph of FIG. 5 indicates the mean or average thickness (in Ångströms or “Å”) per unit time (i.e., minutes) of a film being deposited in the presence of a time-varying electromagnetic field at process stations of a multi-station integrated circuit fabrication chamber. In the example of FIG. 5, under RF balanced conditions, the film deposition taking place at process station 1 (Stn-1) is depicted as occurring at a rate of 1478 Å/min, while film deposition occurring at process stations 2, 3, and 4 (Stn-2, Stn-3, Stn-4) are depicted as comprising values of 1518 Å/min, 1521 Å/min, and 1505 Å/min, respectively. Thus, referring to the equipment arrangement of FIG. 3, although RF power distribution network 323 may be configured to deliver substantially equal allocations of RF power to a multi-station integrated circuit fabrication chamber, variations within individual process chambers may nonetheless bring about nonuniformities in actual in-chamber reaction rates. Utilizing the arrangement of FIG. 3, delivery of substantially equal or balanced allocation of RF power among process stations 1-4 may be brought about by adjusting one or more capacitive elements of RCC modules 324-330 from a nominal or baseline value of about (50%) of a maximum value.

In response to detection of a reduced deposition rate occurring at station 1 of a multi-station fabrication chamber, a capacitance presented by RCC module 324 of FIG. 3 may be adjusted (e.g., decreased) which may at least partially compensate for the nonuniformity within process station 1 (Stn-1) compared to the remaining process stations of the fabrication chamber. Thus, for the example of FIG. 5, responsive to modifying a capacitive reactance presented by RCC module 324, such as from a baseline value of about 50% of a maximum value (RF balanced), to about 35% of the maximum value (RF imbalanced), a deposition rate may be increased. For the particular example of FIG. 5, reduction in capacitive reactance at RCC module 324 may increase a deposition rate at process station 1 (Stn-1) from about 1478 Å/min to about 1505 Å/min. It may also be noted from FIG. 5 that adjustments in capacitive reactance of an RCC module, such as RCC module 324 coupled to process station 1 (Stn-1), appears to have only a negligible impact on film deposition rates occurring in the remaining chambers of a fabrication chamber. For example, adjustment in a capacitive reactance at RCC module 324 from about 50% of a maximum value to about 35% of the maximum value decreases the film deposition rate at process station 2 (Stn-1) by an amount of about 5 Å/min (about 0.33%).

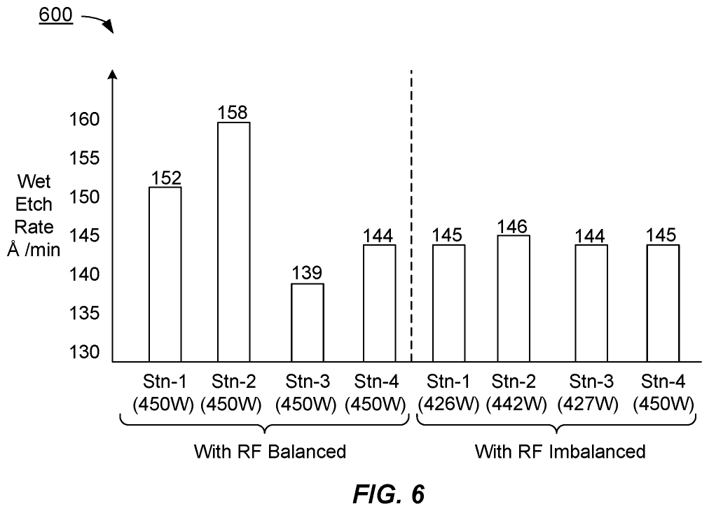

FIG. 6 is a graph showing etch rate of a semiconductor material under a RF power balanced condition and under a RF power imbalanced condition, according to an embodiment 600. The apparatus of FIG. 3 may be suitable for performing an etching process resulting in the graph of FIG. 6, although etching processes may be performed utilizing other arrangements of equipment, and claimed subject matter is not limited in this respect. The vertical axis of the graph of FIG. 6 indicates the wet etch rate, such as may occur during a wet etch process utilizing a 100:1 mixture of hydrogen fluoride (HF) in water in the presence of a time-varying electromagnetic field. In the example of FIG. 6, under RF balanced conditions, the wet etch rate taking place at process station 3 (Stn-3) is depicted as occurring at a rate of 139 Å/min while the wet etch rate occurring at process stations 1, 2, and 4 (Stn-1, Stn-2, Stn-4) are depicted as comprising values of 152 Å/min, 158 Å/min, and 144 Å/min, respectively. Thus, referring to the equipment arrangement of FIG. 3, although RF power distribution network 323 may be configured to deliver substantially equal allocations of RF power to a multi-station integrated circuit fabrication chamber, variations within individual process chambers may nonetheless bring about nonuniformities in actual in-chamber reaction rates. Utilizing the arrangement of FIG. 3, delivery of substantially equal or balanced allocation of RF power among process stations 1-4 may be brought about by adjusting one or more capacitive elements of RCC modules 324-330 to a nominal or baseline value of about 50% of a maximum value.

In response to detection of a reduced etching rate occurring at station 3 of a multi-station fabrication chamber, a capacitive reactance of RCC module 328 of FIG. 3 may be adjusted (e.g., increased), such as from a baseline value of about 50% of a maximum value to about 90% of the maximum value. It should be noted, however, that in particular instances adjustments in capacitive reactance of an RCC module may not bring about a desired increase or decrease in a wet etch rate occurring at a particular process station in relation to the remaining process stations. Thus, in the example of FIG. 6, rather than increasing an etch rate occurring at process station 3 (Stn-3) by way of adjusting capacitive reactance of RCC module 328, it may be advantageous to additionally adjust capacitive reactances of RCC modules 324 and 326 so as to decrease wet etch rates occurring at process stations 1 and 2 (Stn-1 and Stn-2). Accordingly, for the example of FIG. 6, wet etch rates occurring across all process stations of a multi-station fabrication chamber may be brought into uniformity with one another by adjusting capacitive reactance of RCC module 328 and by adjusting capacitive reactance of RCC modules 324 and 326. In the particular example of FIG. 6, such adjustment of capacitive reactances of RCC modules 324-328 may result in a decrease in RF power at process station 1 (Stn-1) from about 450 W to about 426 W, a decrease in RF power at process station 2 (Stn-2) from about 450 W to about 442 W, and a decrease in RF power at process station 3 (Stn-3) from about 450 W to about 427 W.

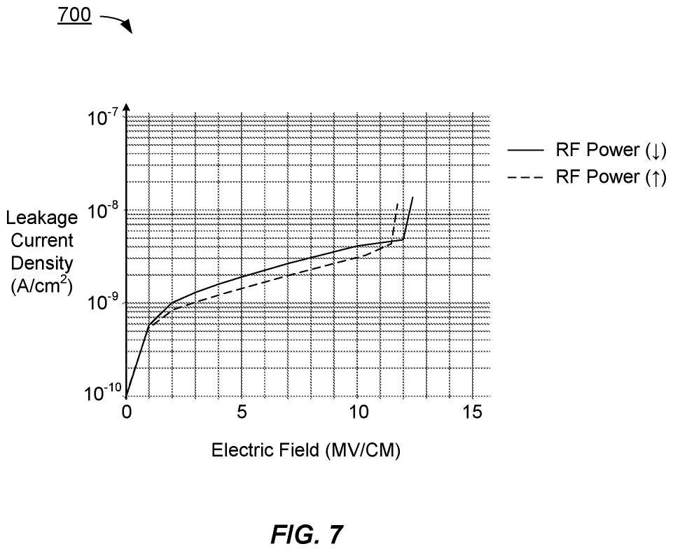

FIG. 7 is a graph showing leakage current of a film deposited on a wafer at a process station under conditions of relatively high and relatively low RF power conditions, according to an embodiment 700. In the embodiment of FIG. 7, leakage current may be measured utilizing a mercury probe, in which highly conductive mercury electrodes having a predetermined surface area are brought into contact with a film. A voltage, which brings about an electric field, may then be applied across the mercury electrodes and the resulting leakage current density, obtained via division of the induced current by the surface area of the mercury probes, can be measured. As indicated in FIG. 7, in particular embodiments, film quality, which in this context refers to leakage current induced in response to an RF-generated electric field, is shown to be higher responsive to a decrease in RF power delivered to a process station. Accordingly, referring to FIG. 7, prior to voltage breakdown, such as under an influence of an electric field of 10 MV/CM (Megavolts/centimeter), a film produced at a process station exposed to decreased RF power (↓ in FIG. 7) results in a leakage current of about 3×10⁻⁹ Amperes/cm². Conversely, a film produced at a process station exposed to increased RF power (↑ in FIG. 7) results in a decreased leakage current, such as about 2×10⁻⁹ Amperes/cm².

In general, with reference to controller 290 of FIG. 2, such controller may be constructing utilizing electronics including various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In the foregoing detailed description, numerous specific details are set forth to provide a thorough understanding of the presented embodiments or implementations. The disclosed embodiments or implementations may be practiced without some or all of these specific details. In other instances, well-known process operations have not been described in detail so as to not unnecessarily obscure the disclosed embodiments or implementations. While the disclosed embodiments or implementations are described in conjunction with the specific embodiments or implementations, it will be understood that such description is not intended to limit the disclosed embodiments or implementations.

The foregoing detailed description is directed to certain embodiments or implementations for the purposes of describing the disclosed aspects. However, the teachings herein can be applied and implemented in a multitude of different ways. In the foregoing detailed description, references are made to the accompanying drawings. Although the disclosed embodiments or implementation are described in sufficient detail to enable one skilled in the art to practice the embodiments or implementation, it is to be understood that these examples are not limiting; other embodiments or implementation may be used and changes may be made to the disclosed embodiments or implementation without departing from their spirit and scope. Additionally, it should be understood that the conjunction “or” is intended herein in the inclusive sense where appropriate unless otherwise indicated; for example, the phrase “A, B, or C” is intended to include the possibilities of “A,” “B.” “C” “A and B,” “B and C.” “A and C.” and “A, B. and C.”

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically includes a diameter of 200 mm, or 300 mm, or 450 mm. The foregoing detailed description assumes embodiments or implementations are implemented on a wafer, or in connection with processes associated with forming or fabricating a wafer. However, the claimed subject matter is not so limited. The work piece may be of various shapes, sizes, and materials. In addition to semiconductor wafers, other work pieces that may take advantage of claimed subject matter may include various articles such as printed circuit boards, or the fabrication of printed circuit boards, and the like.

Unless the context of this disclosure clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also generally include the plural or singular number respectively. When the word “or” is used in reference to a list of two or more items, that word covers all of the following interpretations of the word: any of the items in the list, all of the items in the list, and any combination of the items in the list. The term “implementation” refers to implementations of techniques and methods described herein, as well as to physical objects that embody the structures and/or incorporate the techniques and/or methods described herein.

1. An apparatus to generate radio frequency (RF) power, comprising:
one or more RF power sources; and
a RF power distribution network configured to allocate power from the one or more RF power sources to individual input ports of a multi-station integrated circuit fabrication chamber,
the RF power distribution network additionally configured to apply one or more control parameters to bring about an imbalance in the power from the RF power distribution network to the individual input ports of the multi-station integrated circuit fabrication chamber.

2. The apparatus of claim 1, wherein the RF power distribution network comprises one or more reactive circuit elements.

3. The apparatus of claim 2, further comprising a controller to adjust at least one value of the one or more reactive circuit elements responsive to identification of a disparity between a process condition and/or a process result at a first station of the multi-station integrated circuit fabrication chamber and a process condition and/or process result at a second station of the multi-station integrated circuit fabrication chamber.

4. The apparatus of claim 3, wherein the process condition and/or the process result at the first station and the second station comprises a deposition process.

5. The apparatus of claim 4, wherein the deposition process comprises atomic layer deposition (ALD).

6. The apparatus of claim 4, wherein the deposition process comprises plasma-enhanced chemical vapor deposition (PECVD).

7. The apparatus of claim 3, wherein the process condition and/or the process result at the first station and the second station comprises an etching process.

8. The apparatus of claim 2, wherein the one or more reactive circuit elements comprises at least one capacitor or at least one inductor.

9. The apparatus of claim 8, wherein the one or more reactive circuit elements comprises at least one capacitor, and wherein the one or more control parameters brings about modification of a value of the at least one capacitor to between about 10% and about 90% of a maximum value.

10. A multi-station integrated circuit fabrication chamber, comprising:
one or more input ports each configured to receive a signal from one or more radio frequency (RF) power sources;
a RF power distribution network, coupled to a corresponding one of the one or more input ports, the RF power distribution network comprising one or more reactive circuit elements; and
a controller coupled to the RF power distribution network and configured to modify a value of the one or more reactive circuit elements to give rise to an imbalance in RF power coupled from the one or more RF power sources to the multi-station integrated circuit fabrication chamber.

11. The multi-station integrated circuit fabrication chamber of claim 10, wherein the one or more reactive circuit elements comprises one or more capacitors.

12. The multi-station integrated circuit fabrication chamber of claim 11, wherein the controller is configured to modify a value of capacitance of the one or more capacitors from between about 10% of a maximum value to about 90% of the maximum value.

13. The multi-station integrated circuit fabrication chamber of claim 10, wherein the controller is configured to modify the value of the one or more reactive circuit elements responsive to identification of a difference between a process condition and/or a process result at a first station of the multi-station integrated circuit fabrication chamber and a process condition and/or a process result at a second station of the multi-station integrated circuit fabrication chamber.

14. The multi-station integrated circuit fabrication chamber of claim 13, wherein the process condition and/or the process result at the first station and the second station comprises a deposition process.

15. The multi-station integrated circuit fabrication chamber of claim 13, wherein the process condition and/or the process result at the first station and the second station comprises an etching process.

16. The multi-station integrated circuit fabrication chamber of claim 10, wherein the multi-station integrated circuit fabrication chamber comprises 4 process stations.

17. The multi-station integrated circuit fabrication chamber of claim 10, wherein the multi-station integrated circuit fabrication chamber comprises 2 process stations.

18. The multi-station integrated circuit fabrication chamber of claim 10, wherein the multi-station integrated circuit fabrication chamber comprises 8 process stations.

19. The multi-station integrated circuit fabrication chamber of claim 10, wherein the multi-station integrated circuit fabrication chamber comprises 16 process stations.

20. A control module, comprising:
a hardware processor coupled to a memory; and
a communications port configured to:
receive an indication that a process condition and/or a process result at a first station of a multi-station integrated circuit fabrication chamber is different than a process condition and/or a process result at a second station of the multi-station integrated circuit fabrication chamber; and
transmit one or more instructions to a RF power distribution network to bring about an imbalance in radio frequency (RF) power coupled to the first station of the multi-station integrated circuit fabrication chamber with respect to the RF power coupled to the second station of the multi-station integrated circuit fabrication chamber.

21. The control module of claim 20, wherein the one or more instructions operate to modify a value of one or more reactive elements of the RF power distribution network.

22. The control module of claim 21, wherein the one or more reactive elements comprise at least one capacitor, and wherein the one or more instructions operates to modify the value of the at least one capacitor to between about 10% and about 90% of a maximum value.

23. A method for controlling a fabrication process, comprising:
identifying that a process condition and/or a process result at a first station of a multi-station integrated circuit fabrication chamber is different than a process condition and/or a process result at a second station of the multi-station integrated circuit fabrication chamber; and
imbalancing radio frequency (RF) power coupled to the first station of the multi-station integrated circuit fabrication chamber with respect to the RF power coupled to the second station of the multi-station integrated circuit fabrication chamber.

24. The method of claim 23, wherein imbalancing comprises modifying a value of a reactive circuit element of RF power distribution network coupled to an input port of the multi-station integrated circuit fabrication chamber.

25. The method of claim 24, wherein modifying the value of the reactive circuit element comprises adjusting capacitance of the reactive circuit element from a nominal value of about 50% of a maximum value of capacitance to a value of between about 10% and about 90% of the maximum value of capacitance.

26. The method of claim 23, wherein imbalancing comprises generating at least about a 1% difference between RF power coupled to the first station of the multi-station integrated circuit fabrication chamber with respect to the second station of the multi-station integrated circuit fabrication chamber.

27. The method of claim 23, wherein the process condition and/or the process result at the first station and the second station comprises a deposition process.

28. The method of claim 23, wherein the process condition and/or the process result at the first station and the second station comprises an etching process.
